(19) United States
(12) Patent Application Publication
(10) Pub. No.: US 2016/0035981 A1
(43) Pub. Date: Feb. 4, 2016

(54) ORGANIC SEMICONDUCTOR COMPOUND THIN FILM, METHOD OF FABRICATING THE SAME AND ELECTRONIC DEVICE USING THE SAME

(71) Applicant: GWANGJU INSTITUTE OF SCIENCE AND TECHNOLOGY, Gwangju (KR)

(72) Inventors: Kwanghee LEE, Gwangju (KR); Sooncheol KWON, Gwangju (KR); Kilho YU, Gwangju (KR); Kyoung Chun KWEON, Gwangju (KR)

(21) Appl. No.: 14/446,649

(22) Filed: Jul. 30, 2014

(51) Int. Cl. H01L 51/00; H01L 51/42; H01L 51/05; C08L 41/00; C08L 25/06

(52) U.S. Cl. CPC H01L 51/0036; C08L 41/00; C08L 25/06; H01L 51/0003; H01L 51/0512; H01L 51/42

(57) ABSTRACT

Disclosed herein is an organic semiconductor compound thin film. The organic semiconductor compound thin film includes a conjugated organic material including an unshared electron pair-containing sulfur or nitrogen atom and exhibiting semiconductivity, and a polymeric organic acid bonded to the conjugated organic material through hydrogen bonding and protonation. The organic semiconductor compound thin film exhibits high electric charge mobility and interlayer solvent resistance to facilitate formation of a stack structure despite use of a wet process.

### BACKGROUND

1. Technical Field

The present invention relates to an organic semiconductor compound thin film, a method of fabricating the same, and an electronic device using the same. More particularly, the present invention relates to an organic semiconductor compound thin film exhibiting high electric charge mobility by inducing crystallization of a conjugated organic material via an organic acid, a method of fabricating the same, and an electronic device using the same.

2. Description of the Related Art

Since an organic electronic device using a conjugated polymer has various merits such as low price, very easy manufacturing process, lightweight and bendability as compared with electronic devices based on inorganic materials such as silicon and the like, the organic electronic device using a conjugated polymer is spotlighted as a future energy source and is currently the focus of much research.

To commercialize such an organic material-based electronic device, it is most important to resolve fundamental limiting factors of existing conjugated polymers.

A major limiting factor for determining performance of various organic material-based electronic devices is low electric charge mobility of the conjugated polymers. Such low electric charge mobility is caused by low polymeric crystallinity upon formation of a thin film.

In order to resolve this problem, many studies propose various methods such as: 1) improvement of a polymeric structure; 2) a method using additives; and 3) a method of improving electric charge mobility by improving crystallinity of a conjugated polymer through post treatment, such as thermal annealing and the like.

However, such methods have various limits in solving fundamentally low electric charge mobility of the conjugated polymer.

In fact, the conjugated polymer has extremely high one-dimensional (1-D) electric charge mobility from several dozens of cm²/V·S to several hundreds of cm²/V·S.

However, since the conjugated polymers make three-dimensional (3-D) interaction with each other during change into a solid thin film, that is, a large number of amorphous regions and defect sites are generated during alignment of the conjugated polymers from side to side or from top to bottom, the conjugated polymers finally exhibit low charge carrier mobility in a device.

Recently, to solve such a problem, surface crystal seeds are formed through interaction between a surface of a substrate and the conjugated polymer by performing self-assembled monolayer (SAM) post-treatment on the substrate, and grown into crystals having an orientation upon formation of a thin film.

However, induction of crystallinity only to the substrate surface is insufficient to induce overall crystallinity of the thin film through a total thickness (about 70 nm to about 80 nm) thereof.

### BRIEF SUMMARY

It is an aspect of the present invention to provide an organic semiconductor compound thin film exhibiting high electric charge mobility on a flexible substrate by inducing crystallization of a conjugated organic material at room temperature.

It is another aspect of the present invention to provide an organic semiconductor compound thin film exhibiting interlayer solvent resistance such that formation of a stack structure can be facilitated despite use of a wet process.

It is a further aspect of the present invention to provide a method of fabricating the organic semiconductor compound thin film and to provide an electronic device using the organic semiconductor compound thin film.

In accordance with one aspect of the present invention, an organic semiconductor compound thin film may include: a conjugated organic material including an unshared electron pair-containing sulfur or nitrogen atom and exhibiting semiconductivity; and a polymeric organic acid bonded to the conjugated organic material through hydrogen bonding and protonation.

Here, the conjugated organic material may be P3HT, PDVT-10, PQT, or DTS(PTTh₂)₂. In addition, the polymeric organic acid may be PSS.

In accordance with another aspect of the present invention, a method of fabricating an organic semiconductor compound thin film may include: preparing a first dispersion in which a conjugated organic material including an unshared electron pair-containing sulfur or nitrogen atom and exhibiting semiconductivity is dissolved in an organic solvent; forming a crystal seed, in which the conjugated organic material and a polymeric organic acid are bonded to each other, by adding the polymeric organic acid to the first dispersion; and forming an organic semiconductor compound thin film by coating the first dispersion having the crystal seed formed therein onto a solid matrix.

In accordance with a further aspect of the present invention, an organic electronic device includes the organic semiconductor compound thin film as set forth above.

The organic electronic device may be an organic solar cell including the organic semiconductor compound thin film as an electron donor layer.

In addition, the organic electronic device may be an organic field effect transistor including the organic semiconductor compound thin film as an active layer.

According to the present invention, since crystallization of a conjugated organic material is induced at room temperature by adding a polymeric organic acid to the conjugated organic material exhibiting semiconductivity, the organic semiconductor compound thin film exhibiting high electric charge mobility can be formed on a flexible substrate.

In addition, the organic semiconductor compound thin film exhibiting interlayer solvent resistance can be provided such that formation of a stack structure can be facilitated despite use of a wet process.

Further, the organic electronic device exhibiting improved lateral and vertical electric charge mobility can be provided using the organic semiconductor compound thin film.

### BRIEF DESCRIPTION OF THE DRAWINGS

The above and other aspects, features, and advantages of the present invention will become apparent from the detailed description of the following embodiments in conjunction with the accompanying drawings;

FIG. 1 is a flowchart of a method of fabricating an organic semiconductor compound thin film according to one embodiment of the present invention;

FIG. 2 shows a mechanism of generating attractive force between P3HT corresponding to a conjugated organic material and PSS corresponding to a polymeric organic acid;

FIG. 3 shows images of solutions including crystal seeds formed in dispersions obtained by adding PSS to P3HT;

FIG. 4 shows HADDF-STEM images of P3HT and P3HT:PSS thin films over time;

FIG. 5 shows C-AFM images of P3HT and P3HT:PSS thin films;

FIG. 6 shows histograms of P3HT and P3HT:PSS thin films;

FIG. 7 shows graphs depicting properties of P3HT:PSS thin films;

FIG. 8 shows images and graphs of a P3HT:PSS thin film, as measured through grazing incidence wide-angle X-ray scattering (GIWAXS);

FIG. 9 is a graph depicting vertical electric charge mobility of P3HT and P3HT:PSS thin films in a space charge limited current (SCLC) region;

FIG. 10 shows graphs depicting characteristics of OFET devices using P3HT, P3HT:PSS, PDVT-10, PDVT-10:PSS, DTS(PTTh₂)₂, and DTS(PTTh₂)₂:PSS thin films, respectively;

FIG. 11 shows graphs depicting output characteristics of OFET devices using PDVT-10, PDVT-10:PSS, DTS(PTTh₂)₂, and DTS(PTTh₂)₂:PSS thin films, respectively;

FIG. 12 shows graphs depicting resistance characteristics of P3HT and P3HT:PSS thin films, respectively;

FIG. 13 shows graphs depicting lifespan characteristics of OFET devices using P3HT and P3HT:PSS thin films, respectively;

FIG. 14 is a schematic diagram of an organic solar cell using a P3HT:PSS thin film;

FIG. 15 shows graphs depicting characteristics of organic solar cells using P3HT and P3HT:PSS thin films, respectively;

FIG. 16 shows a mechanism of generating attractive force between PQT-12 as a conjugated organic material and PSS as a polymeric organic acid;

FIG. 17 shows graphs depicting characteristics of OFET devices using PQT:PSS thin films; and

FIG. 18 shows graphs depicting characteristics of OFET devices using PQT:PSS thin films.

### DETAILED DESCRIPTION

Hereinafter, embodiments of the present invention will be described in detail with reference to the accompanying drawings.

It should be understood that the following embodiments are provided for illustration only and are not to be construed in any way as limiting the present invention, and that various modifications, changes, alterations, and equivalent embodiments can be made by those skilled in the art without departing from the spirit and scope of the invention. Therefore, the scope of the invention should be limited only by the accompanying claims and equivalents thereof.

It will be understood that when an element such as a layer, film, region or substrate is referred to as being placed “on” another element, it can be directly placed on the other element, or intervening layer(s) may also be present.

Although terms such as first, second and the like may be used to describe various elements, components, areas, layers and/or regions, it will be understood that such terms are not to be construed as limiting such elements, components, areas, layers and/or regions.

Now, an organic semiconductor compound thin film according to one embodiment of the present invention will be described in detail.

The organic semiconductor compound thin film includes a conjugated organic material and a polymeric organic acid bonded to the conjugated organic material through hydrogen bonding and protonation.

The conjugated organic material includes an unshared electron pair-containing sulfur or nitrogen atom and exhibits semiconductivity.

The conjugated organic material exhibiting semiconductivity may be a conjugated polymer or a conjugated small molecule.

For example, the conjugated polymer may be poly(3-hexylthiophen) (P3HT), poly[2,5-bis(alkyl)pyrrolo[3,4-c]pyrrole-1,4(2H,5H)-dione-alt-5,5′-di(thiophen-2-yl)-2,2′-(E)-2-(2-(thiophen-2-yl)vinyl)thiophene] (PDVT-10), or poly(3,3′-didodecyl-quarterthiophen) (PQT). In addition, the conjugated small molecule may be, for example, DTS(PTTh₂)₂.

If the conjugated organic material is formed into a solid thin film, the solid thin film can exhibit low electric charge mobility due to low polymeric crystallinity.

Thus, crystal seeds are formed by bonding the conjugated organic material to the polymeric organic acid, thereby enabling formation of the organic semiconductor compound thin film, in which a network is formed through induction of crystallization by the previously formed crystal seeds upon formation of the solid thin film. As a result, the organic semiconductor compound thin film exhibiting high electric charge mobility can be formed. Here, the crystal seeds refer to low-dimensional or one-dimensional (1D) seeds.

The polymeric organic acid may be any material that can be bonded to the unshared electron pair-containing sulfur or nitrogen atoms in the conjugated organic material through hydrogen bonding and protonation.

For example, the polymeric organic acid may be poly(styrenesulfonic acid) (PSS).

Thus, crystallization of the conjugated organic material is induced by adding the polymeric organic acid to the conjugated organic material exhibiting semiconductivity, thereby providing an organic semiconductor compound thin film exhibiting high electric charge mobility.

In addition, since the organic semiconductor compound thin film according to the present invention has a surface composed of the conjugated polymer and the polymeric organic acid and thus exhibits interlayer solvent resistance despite use of a wet process, the organic semiconductor compound thin film enables formation of a more uniform and stable stack structure.

Therefore, an organic electronic device exhibiting improved performance can be provided using the organic semiconductor compound thin film according to the present invention.

That is, the organic semiconductor compound thin film according to the present invention may be widely applied to inverse-structure solar cells, solar cell stacks, thin film transistors, sensors, energy storage devices, and combinations thereof.

In one example, the organic semiconductor compound thin film may be applied to an organic solar cell. The organic solar cell may include a cathode, an anode, and a photoactive layer which is interposed between the cathode and the anode and includes an electron donor layer and an electron acceptor layer. Here, the organic semiconductor compound thin film according to the present invention may be used as the electron donor layer. For example, a P3HT:PSS thin film may be used as the electron donor layer.

In another example, the organic semiconductor compound thin film may be applied to an organic field effect transistor. The organic field effect transistor may include a source electrode, a drain electrode, and an active channel interposed between the source electrode and the drain electrode. Here, the organic semiconductor compound thin film according to the present invention may be used as the active channel. For example, a P3HT:PSS, PDVT-10:PSS, PQT12:PSS or DTS(PTTh2)2:PSS thin film may be used as the active channel.

Now, a method of fabricating an organic semiconductor compound thin film according to one embodiment of the present invention will be described in detail with reference to the accompanying drawings.

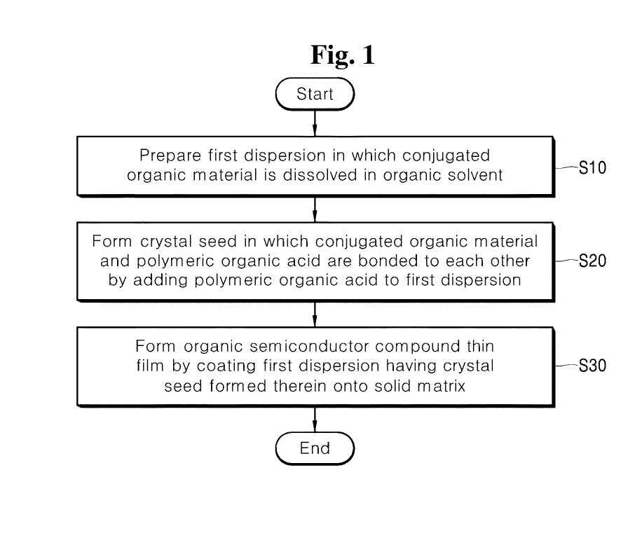

FIG. 1 is a flowchart of a method of fabricating an organic semiconductor compound thin film according to one embodiment of the present invention.

Referring to FIG. 1, first, a first dispersion, in which a conjugated organic material including an unshared electron pair-containing sulfur or nitrogen atom and exhibiting semiconductivity is dissolved in an organic solvent (S10), is prepared.

The conjugated organic material may be a conjugated polymer or a conjugated small molecule. For example, the conjugated polymer may be P3HT, PDVT-10, or PQT. In addition, the conjugated small molecule may be, for example, DTS(PTTh₂)₂.

Next, a polymeric organic acid is added to the first dispersion, thereby forming a crystal seed in which the conjugated organic material and the polymeric organic acid are bonded to each other (S20).

Here, the polymeric organic acid may be PSS.

Here, the conjugated organic material forms strong electrostatic attractive force causing chemical doping through hydrogen bonding to the polymeric organic acid and protonation, thereby forming crystal seeds for inducing crystallinity.

For example, as the polymeric organic acid, PSS may be added to the first dispersion in which P3HT is dissolved as the conjugated organic material, thereby forming crystal seeds in which P3HT and PSS are bonded to each other.

Next, the first dispersion having the crystal seeds formed therein is coated onto a solid matrix to form an organic semiconductor compound thin film (S30).

Here, the solid matrix may be any solid matrix regardless of surface properties thereof. For example, when the organic semiconductor compound thin film is used as an electron donor layer of a stacked solar cell, the solid matrix may be a PEDOT:PSS hole transporting layer or an ITO cathode. In addition, when the organic semiconductor compound thin film is used as an active channel of an OFET device, the solid matrix may be a Si substrate, a Si/SiO₂ substrate, or a flexible plastic substrate.

Thus, since the first dispersion, in which the crystal seeds are formed by bonding the polymeric organic acid to the conjugated organic material, is used, a three-dimensional network can be formed through induction of crystallization by the crystal seeds upon formation of a solid thin film. That is, the organic semiconductor compound thin film exhibiting high vertical and lateral electric charge mobility can be formed.

In addition, the organic semiconductor compound thin film formed in this way can provide advantages in a stacking process. Basically, although a solvent not dissolving an under layer must be selected to stack two or more organic semiconductor layers via a wet process, it is difficult to find a solvent that does not dissolve the under layer at all due to properties of organic solvents.

However, since PSS, which is the polymeric organic acid in the organic semiconductor compound thin film according to the present invention, is a water-soluble polar molecule, PSS exhibits resistance to most non-polar organic solvents. Thus, since PSS is actually distributed throughout a significantly large number of sites on a surface of the thin film, PSS can effectively prevent solvent permeation and thus prevent two layers from being mixed.

### Mechanism of Generating Attractive Force Between P3HT and PSS

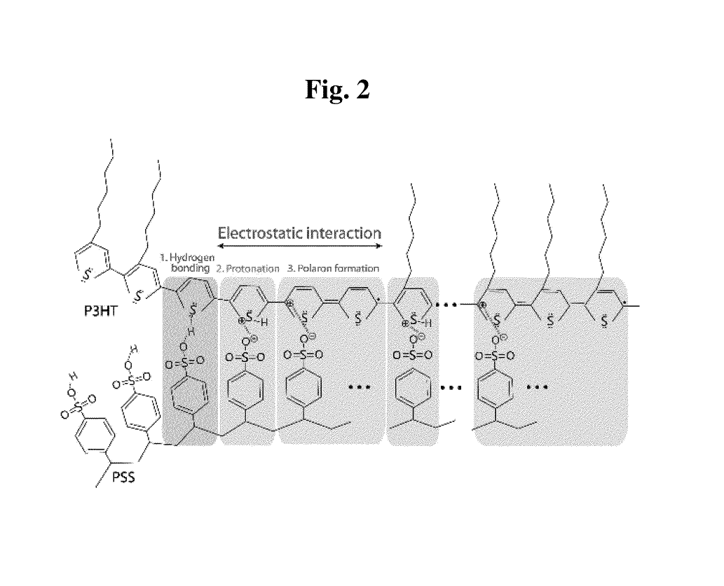

FIG. 2 shows a mechanism of generating attractive force between P3HT as a conjugated organic material and PSS as a polymeric organic acid.

Referring to FIG. 2, three reasons for induction of crystallization by crystal seeds in a solution are as follows.

First is hydrogen bonding.

Since SO₃—H of PSS interacts with an unshared electron pair of sulfur of P3HT, a strong hydrogen bond (S—H) can be created. This basically facilitates chemical reaction through decrease in distance between the two molecules.

Second is protonation.

Hydrogen of SO₃—H of PSS in the hydrogen bond can easily depart therefrom and then be transported to a sulfur atom of P3HT, thereby causing protonation. Here, the sulfur atom exhibits relatively insufficient electric charge.

This causes electrostatic attractive force between an anionized SO₃-group and a cationized sulfur ion.

Third is formation of a polaron within P3HT.

Since protonation changes an electronic structure within P3HT and allows formation of the polaron within P3HT, P3HT is in a cationic form having relatively insufficient electrons therein as in the sulfur atom.

This causes electrostatic attractive force between the anionized SO₃-group and the cationized P3HT.

In particular, strong attractive force between PSS and P3HT can be formed in the form of an extremely sturdy rod, which in turn becomes a long crystal seed for inducing crystallinity.

As such, several crystal seeds, which are already formed in the solution and grown in rod form, induce crystallinity upon formation of the thin film, unlike existing methods in which crystallinity is induced by annealing or solvent treatment after film formation.

### EXPERIMENTAL EXAMPLE 1

In each of four glass vials, 10 mg of P3HT as a conjugated polymer and 1 ml of chloroform were placed, followed by stirring at room temperature for 1 hour.

Next, 0 mg, 11 mg, 55 mg, and 111 mg of PSS (18% by weight (wt %) in water) were placed in the four glass vials, respectively, followed by stirring at room temperature for about 72 hours. Here, weight ratios of P3HT to PSS were 1:0, 1:0.2, 1:1, and 1:2, respectively.

Next, the solutions prepared in this way were coated onto a substrate to form P3HT and P3HT:PSS thin films having a thickness from about 70 nm to about 100 nm

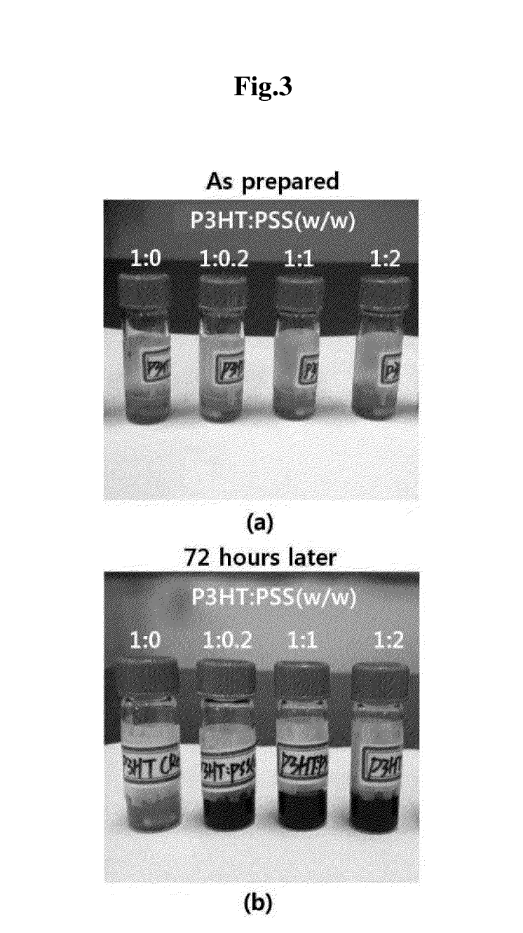

FIG. 3 shows images of crystal seeds formed in dispersions obtained by adding PSS to P3HT.

In FIG. 3, changes occurring between P3HT and PSS over time are shown.

FIG. 3(a) shows an image of dispersions as-prepared by adding PSS to a P3HT solution in weight ratios of P3HT to PSS of 1:0, 1:0.2, 1:1 and 1:2, respectively, and FIG. 3(b) shows an image of the dispersions of FIG. 3(a) after 72 hours.

Here, the solution to which PSS was added in a weight ratio of P3HT to PSS of 1:0 refers to a P3HT reference solution (Ref.) to which PSS was not added.

Referring to FIGS. 3(a) and 3(b), unlike the pure P3HT dispersion, it can be observed that the dispersions including PSS changed to a dark color with decreasing photoluminescence over time.

From this result, for the aforementioned two reasons, it can be seen that PSS and P3HT molecules were maintained at close distances therebetween, and that interaction between the P3HT molecules became extremely strong.

That is, it can be seen that the crystal seeds for inducing crystallinity upon thin film formation were formed.

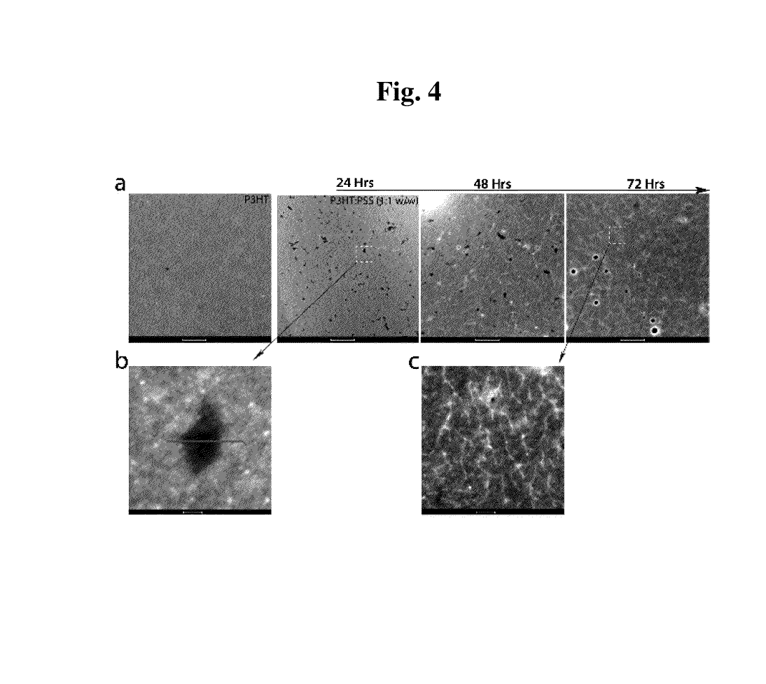

FIG. 4 shows HADDF-STEM images of P3HT and P3HT:PSS thin films over time. FIG. 4(a) shows images of the P3HT thin film, to which PSS was not added, and P3HT:PSS thin films over time (24 h, 48 h, and 72 h), respectively.

Although the P3HT thin film did not show a great change, irregular-shape black dots were observed 24 hours after addition of PSS to P3HT. FIG. 4(b) shows EDS analysis graphs of the black dots. From the analysis results, it can be seen that the dots contained a relatively large amount of oxygen and thus were PSS. After 48 hours, the black dots gradually disappeared and white fibril structures appeared. Finally, after 72 hours, it was observed that the black dots had almost completely disappeared and the white fibril structures were entangled in a network.

In HADDF-STEM, a black portion means relatively low electron distribution and a white portion means relatively high electron distribution. Thus, it can be anticipated that the white fibril structures and the well-distributed network have great influence on electric charge mobility.

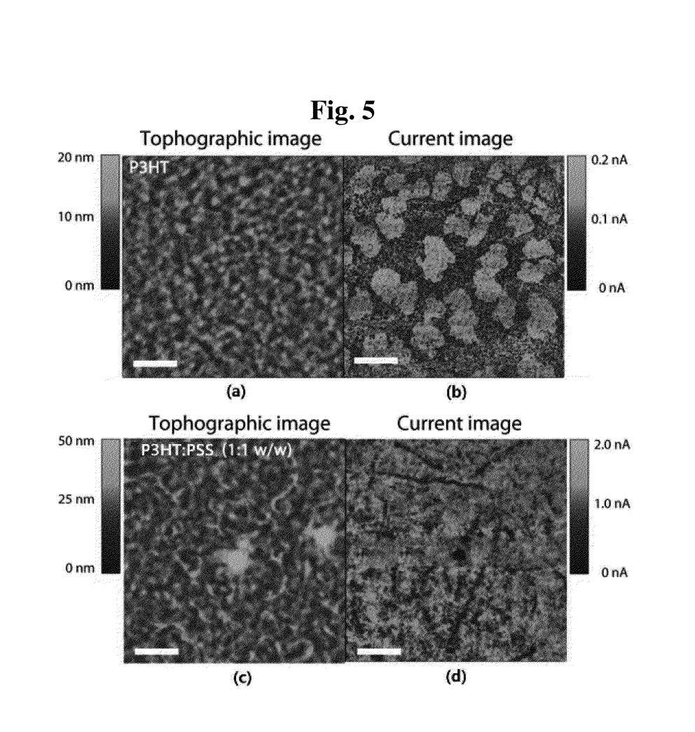

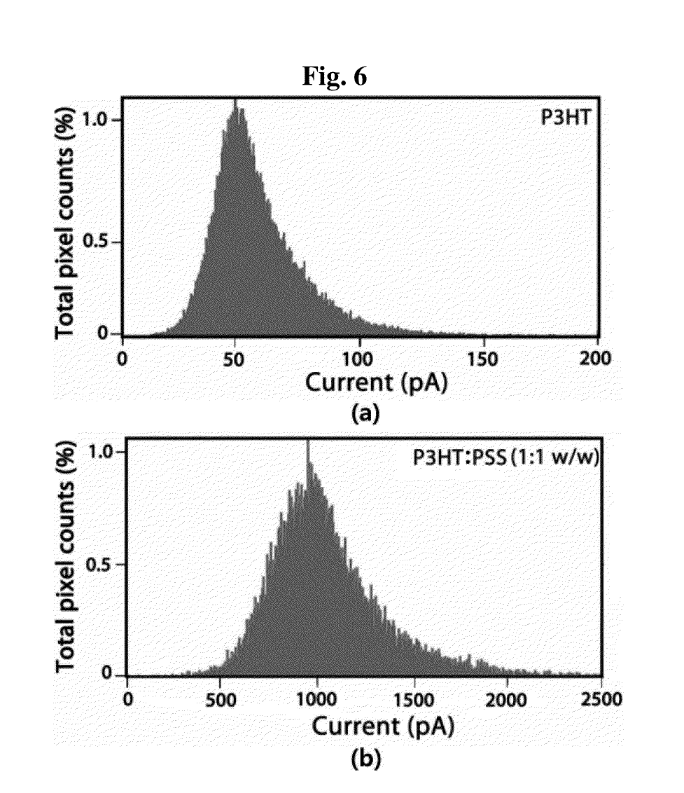

FIG. 5 shows C-AFM images of P3HT and P3HT:PSS thin films. FIG. 6 shows histograms of P3HT and P3HT:PSS thin films.

In addition, FIG. 5(a) shows a topographic image and a current image of a P3HT thin film to which PSS was not added, and FIG. 5(b) shows a topographic image and a current image of a P3HT:PSS (1:1 w/w) thin film.

Further, FIG. 6(a) shows a histogram of a P3HT thin film to which PSS was not added, and FIG. 6(b) shows a histogram of a P3HT:PSS (1:1 w/w) thin film.

There was no particular change observed in the topographic image of the pure P3HT thin film which was not subjected to any treatment.

However, when current flow was measured on this surface, a region in which high current flows in a domain size from about 200 nm to about 1 μm was observed. However, it can be seen that planar current flow was extremely limited due to relatively low current flow in the vicinity of a domain boundary.

When the PSS organic acid was added to P3HT in a weight ratio of P3HT to PSS of 1:1, there was no great change observed in the topographic image, although a winding skein shape was observed.

However, from the measurement results of current flow, since the domain boundary was completely collapsed while increasing the overall amount of current flow, it can be confirmed that the network was formed well.

Thus, in comparison of current images of FIGS. 5(a) to 5(b), it can be seen that the P3HT:PSS thin film (1:1 w/w) had a better network than the P3HT thin film.

In addition, in comparison of histograms of FIGS. 6(a) to 6(b), it can be seen that the P3HT:PSS thin film (1:1 w/w) had a significantly larger amount of current flow than the P3HT thin film.

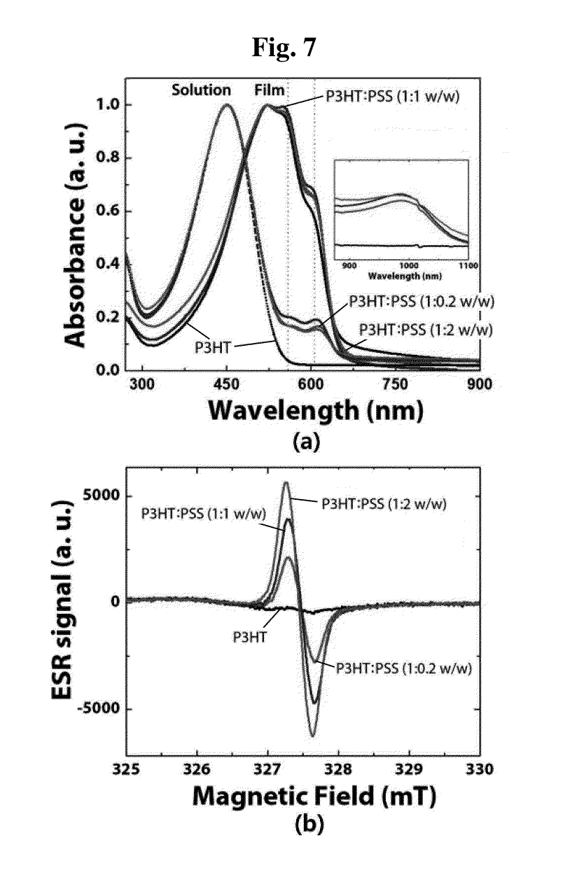

FIG. 7 shows graphs depicting properties of P3HT:PSS thin films.

FIG. 7(a) shows a graph depicting absorbance of a solution state and absorbance of a film state.

Referring to FIG. 7(a), it can be seen that, since an electron vibronic shoulder peak was clearly observed and, in particular, there was the same trend in the case of absorbance in a solution state, a crystal form was already formed to some degree in the solution. That is, it can be seen that crystal seeds were formed in the solution.

An image inserted in the graph of FIG. 7(a) shows polaron absorption, and shows absorption peaks when the thin films were doped.

FIG. 7(b) shows electron spin resonance (ESR) spectra.

Referring to FIG. 7(b), although there was no change observed in the P3HT solution, it can be seen that the P3HT:PSS (1:0.2 w/w, 1:1 w/w, and 1:2 w/w) solutions included radical ions present therein. From this result, it can be seen that the P3HT:PSS (1:0.2 w/w, 1:1 w/w, and 1:2 w/w) solutions were chemically doped.

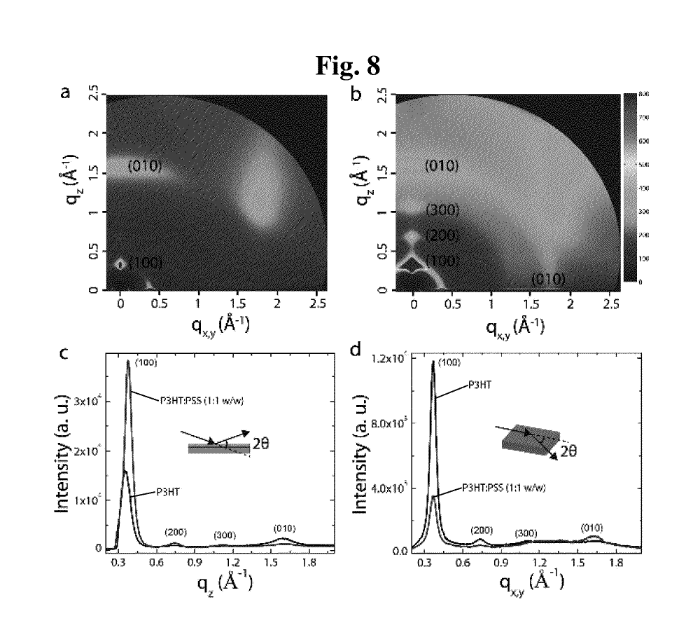

FIG. 8 shows images and graphs of a P3HT:PSS thin film, as measured through grazing incidence wide-angle X-ray scattering (GIWAXS). FIG. 8 shows graphs obtained by measuring the P3HT and P3HT:PSS (1:1 w/w) thin films through GIWAXS.

FIG. 8(a) shows an image obtained by measuring crystallinity changes of the P3HT thin film, and FIG. 8(b) shows an image obtained by measuring crystallinity changes of the P3HT:PSS (1:1 w/w) thin film.

In addition, FIGS. 8(c) and 8(d) shows 1-D graphs of the P3HT and P3HT:PSS thin films, which were extracted from the images.

Referring to FIGS. 8(c) to 8(d), P3HT includes crystals grown therein at intermolecular distances of 17.2 A at q=0.37 A⁻¹ (Lamella stacking) and of 3.95 A at q=1.60 Å⁻¹ (p-p stacking), respectively. As a result of addition of PSS to P3HT, since in-plane p-p stacking of P3HT was significantly increased, it can be seen that crystallinity of P3HT greatly varied.

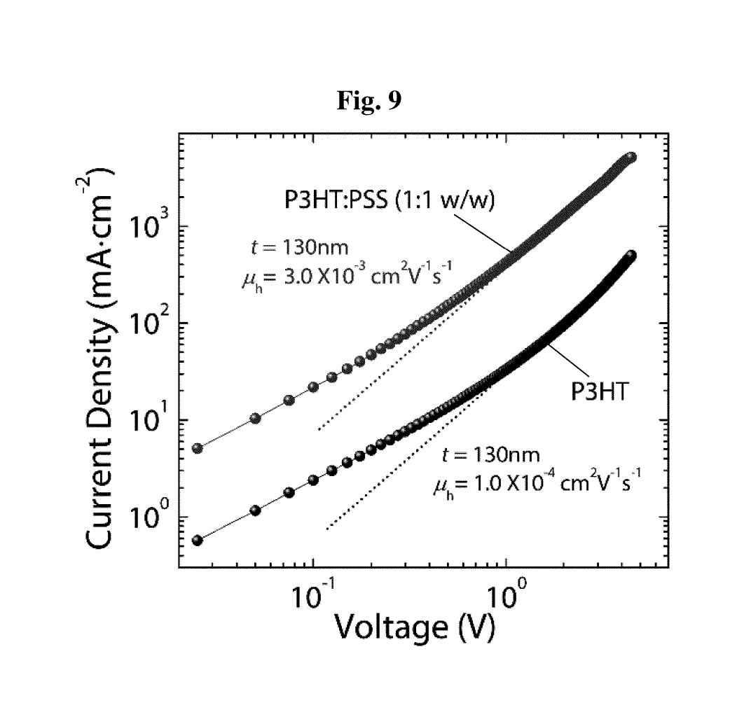

FIG. 9 is a graph depicting vertical electric charge mobility of P3HT and P3HT:PSS thin films in a space charge limited current (SCLC) region.

The P3HT thin film had μ=1.0×10⁻⁴ cm2 V⁻¹ s⁻¹, whereas the P3HT:PSS thin film had μ=3.0×10⁻³ cm² V⁻¹ s⁻¹. Thus, the P3HT:PSS thin film exhibited an about 30-fold increase in electric charge mobility. In addition, since SCLC mobility is vertical electric charge mobility, this result means that the P3HT:PSS thin film had greatly increased vertical electric charge mobility.

### EXPERIMENTAL EXAMPLE 2

OFET devices using solutions obtained by adding PSS to various conjugated polymers and stirring these materials were analyzed. In this experiment, a conjugated polymer thin film or a conjugated polymer:PSS thin film was formed as a semiconductor layer on a Si/Si0₂ substrate, followed by forming a gate electrode (G) at a lower side of the

Si/Si0₂ substrate. Next, a source electrode (S) and a drain electrode (D) were formed to be separated from each other on the conjugated polymer thin film or the conjugated polymer:PSS thin film, thereby preparing an OFET device (L=50 μm, W=1000 μm). Here, a region of the semiconductor layer between the source electrode (S) and the drain electrode (D) corresponds to an active layer channel.

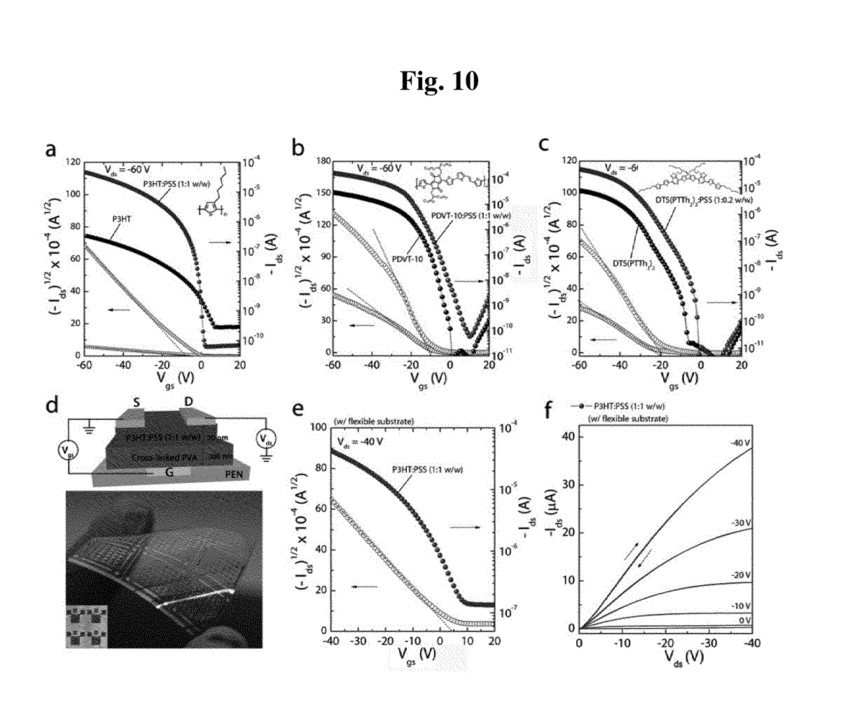

FIG. 10(a) shows transfer curves depicting characteristics of the OFET devices using P3HT and P3HT:PSS thin films, respectively.

FIG. 10(b) shows transfer curves depicting characteristics of the OFET devices using PDVT-10 and PDVT-10:PSS thin films, respectively. FIG. 10(c) shows transfer curves depicting characteristics of the OFET devices using DTS(PTTh₂)₂ and DTS(PTTh₂)₂:PSS thin films, respectively. A transfer curve shows characteristics of a FET electronic device. FIG. 10(b) shows output curves for the curves of FIG. 10(a). The output curves depict electric charge mobility depending upon weight ratios of added PSS.

TABLE 1

| | | | | On/off |
|---|---|---|---|---|
| Materials | μ (cm²V⁻¹s⁻¹) | Vₜₕ (V) | S (V/decade) | ratio |
| P3HT | 8.84 × 10⁻⁴ | −2 | 3 | 9.1 × 10³ |
| P3HT:PSS | 1.8 × 10⁻¹ | −7 | 1.2 | 1.0 × 10⁶ |
| (1:1 w/w) | | | | |
| PDVT-10 | 1.3 × 10⁻¹ | −8 | 1.5 | 1.0 × 10⁶ |
| PDVT-10:PSS | 1.1 × 10⁰ | −10 | 1.1 | 1.0 × 10⁷ |
| (1:1 w/w) | | | | |
| DTS(PTTh₂)₂ | 3.1 × 10⁻² | −20 | 1.8 | 1.0 × 10⁶ |
| DTS(PTTh₂)₂:PSS | 2.7 × 10⁻¹ | −15 | 1.7 | 1.0 × 10⁷ |
| (1:0.2 w/w) | | | | |

Referring to FIG. 10 and Table 1, as a result of mixing PSS with various conjugated polymers, optimal conditions varied depending upon the conjugated polymers, and reaction time also varied depending upon the conjugated polymers. Particularly, for DTS(PTTh₂)₂, the weight ratio of DTS(PTTh₂)₂ to PSS was 1:0.2, and thus optimal conditions were obtained at an extremely small amount of PSS and for a rapid reaction time of about 1 day.

From this result, it can be seen that a molecular volume and the like can have a great influence on interaction and reaction time in interaction between the PSS polymeric organic acid and the conjugated material.

Table 1 shows comparison results of performance of OFETs using various conjugated polymers and conjugated polymer:PSS thin films. Although most of the conjugated polymers, which were not subjected to any treatment, exhibited low electric charge mobility, the conjugated polymers after PSS treatment exhibited significantly increased electric charge mobility of up to 100 times the electric charge mobility before PSS treatment.

Therefore, it can be seen that low molecular weight molecules or even extremely low molecular weight monomers as well as polymers can realize high electric charge mobility through interaction with PSS so long as elements capable of interacting with PSS are present therein.

FIG. 10(d) shows an image of an OFET device in which a P3HT:PSS thin film was formed on a flexible substrate (PEN).

FIG. 10(e) shows transfer characteristics of the OFET formed on the flexible thin film.

TABLE 2

| Materials | μ (cm²V⁻¹s⁻¹) | Vₜₕ (V) | S (V/decade) | On/off ratio |
|---|---|---|---|---|
| P3HT:PSS (1:1 | 2.5 × 10⁻¹ | 4 | 2.1 | 1.0 × 10³ |
| w/w) on flexible | | | | |
| substrate | | | | |

Table 2 shows performance results of the OFET formed on the flexible thin film.

FIG. 10(f) shows output characteristics of the OFET formed on the flexible thin film. The results show that high-performance electronic devices can be realized due to crystallization at room temperature even without separate annealing.

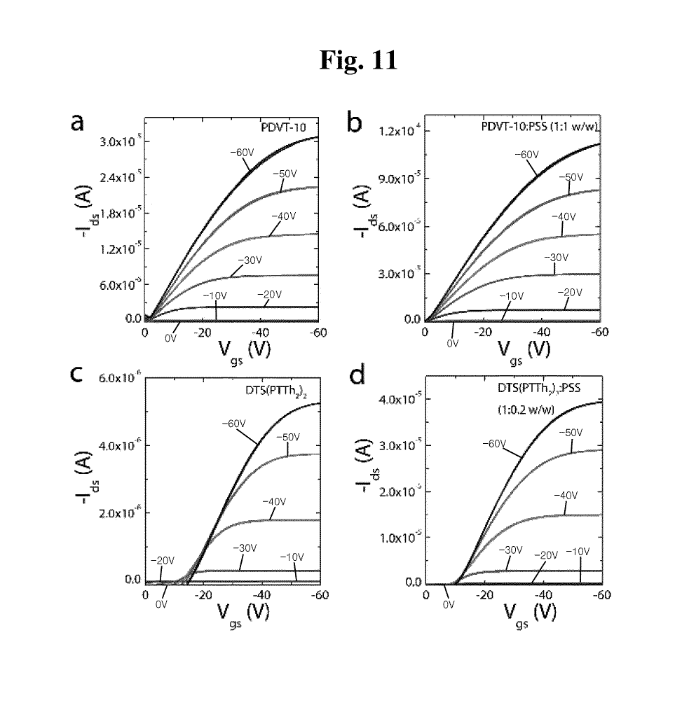

FIGS. 11(a) and 11(b) shows output characteristics of the OFETs using the PDVT-10 thin film and the PDVT-10:PSS (1:1 w/w) thin film of FIG. 10(b), respectively.

FIGS. 11(c) and 11(d) shows output characteristics of the OFETs using the DTS(PTTh₂)₂ thin film and the DTS(PTTh₂)₂:PSS (1:1 w/w) thin film of FIG. 10(c), respectively.

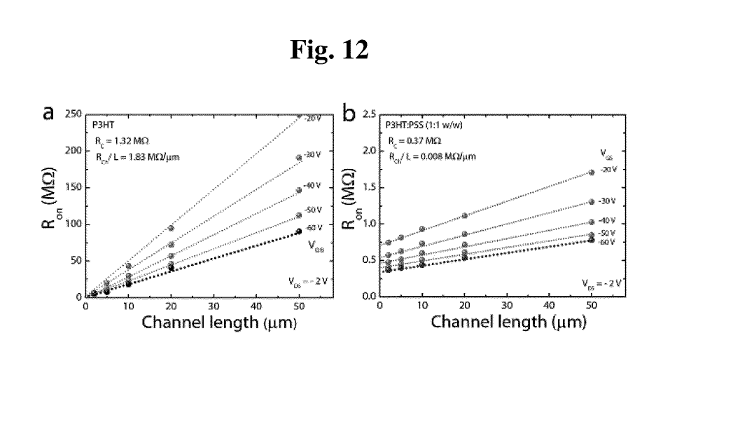

FIGS. 12(a) and 12(b) are graphs depicting contact resistance (R_{c}) and channel resistance (R_{ch}/L) of the OFETs using the P3HT thin film and the P3HT:PSS (1:1 w/w) thin film, respectively.

Referring to FIGS. 12(a) and 12(b), when PSS was added to the thin film, it can be seen that the OFET had R_{c} reduced by about 3-fold to about 4-fold and R_{ch}/L reduced by almost 100-fold or more. Thus, it can be seen that the OFET using the PSS-added thin film had increased electric charge mobility due to significant reduction in channel resistance.

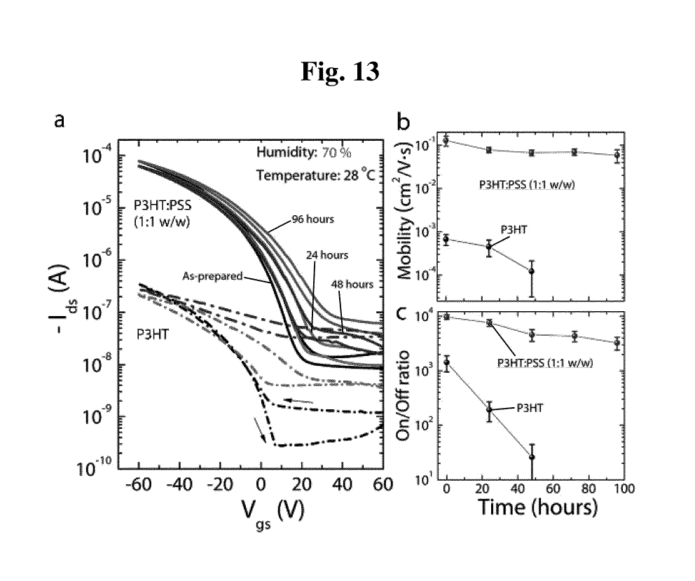

FIG. 13 shows graphs depicting lifespan characteristics of OFET devices using P3HT and P3HT:PSS (1:1 w/w) thin films, respectively.

FIG. 13(a) shows changes in transfer characteristics of OFET devices using P3HT and P3HT:PSS (1:1 w/w) thin films over time.

FIGS. 13(b) and 13(c) show electric charge mobility and on/off ratio calculated in FIG. 13(a), respectively. From the measurement results, the OFET using the P3HT:PSS thin film had better lifespan than the OFET using the P3HT thin film. As a reason for this result, it is believed that, although PSS exhibited non-conductor properties, PSS was distributed on the surface of the thin film upon formation of the P3HT:PSS thin film and thus served to prevent moisture and oxygen permeation.

### EXPERIMENTAL EXAMPLE 3

An organic solar cell using a P3HT:PSS thin film according to one embodiment of the present invention was prepared, followed by analyzing characteristics thereof.

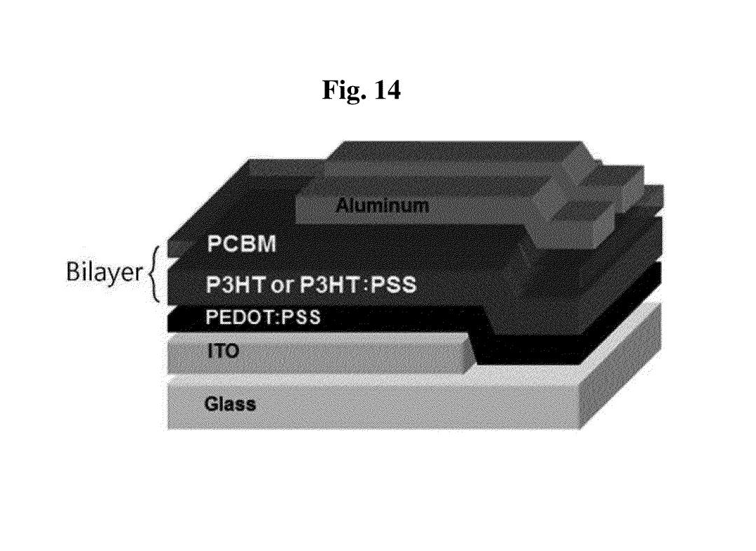

FIG. 14 is a schematic diagram of an organic solar cell using a P3HT:PSS thin film.

Referring to FIG. 14, a organic solar cell stack was prepared by sequentially stacking an ITO electrode, a PEDOT:PSS hole transporting layer, a photoactive layer and an aluminum electrode on a glass substrate.

Here, the photoactive layer has a bi-layer structure including an electron donor layer and an electron acceptor layer formed on the electron donor layer. Here, the electron to donor layer was prepared using a P3HT thin film or a P3HT:PSS thin film, and the electron acceptor layer was prepared using a PCMB thin film.

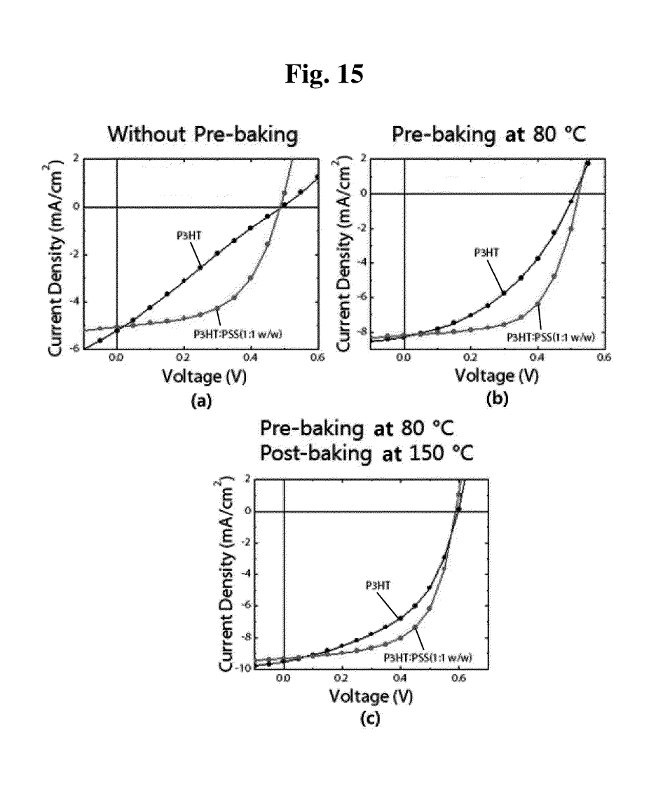

FIG. 15 shows graphs depicting characteristics of organic solar cells using P3HT and P3HT:PSS thin films, respectively.

Referring to FIG. 15, changes in performance of organic solar cell stacks in response to annealing were measured.

TABLE 3

| | | V_{oc} | J_{sc} | | |
|---|---|---|---|---|---|
| | | (V) | (mA/cm²) | F.F. | PEC (%) |
| Without Baking | P3HT/PCBM (Bi-layer) | 0.49 | 5.2 | 0.25 | 0.6 |
| Without Baking | P3HT:PSS(1:1 w/w)/PCBM (Bi-layer) | 0.49 | 5.1 | 0.54 | 1.4 |
| Pre-baking (80° C.) | P3HT/PCBM (Bi-layer) | 0.51 | 8.3 | 0.41 | 1.7 |
| Pre-baking (80° C.) | P3HT:PSS(1:1 w/w)/PCBM (Bi-layer) | 0.52 | 8.2 | 0.60 | 2.6 |
| Pre-baking (80° C.) and | P3HT/PCBM (Bi-layer) | 0.60 | 9.5 | 0.48 | 2.7 |
| Post-baking (150° C.) | | | | | |
| Pre-baking (80° C.) and | P3HT:PSS(1:1 w/w)/PCBM (Bi-layer) | 0.60 | 9.6 | 0.61 | 3.5 |
| Post-baking (150° C.) | | | | | |

Table 3 shows performance results of the organic solar cell stacks upon annealing.

Referring to FIG. 15 and Table 3, although crystallinity is generally induced by post-treatment, such as annealing and the like, for high efficiency in P3HT-based organic solar cells, since crystallinity of P3HT is induced in a solution in advance by addition of PSS, the organic solar cell exhibited high performance even without annealing.

In particular, the organic solar cell using the thin film which was not subjected to annealing (FIG. 15(a)) had a 2-fold or more difference in efficiency.

In addition, even after final annealing, the organic solar cell using the P3HT thin film in which crystallinity was induced by PSS exhibited the best performance of 3.5%, and this value was a 30% or more increased value, as compared with existing P3HT-based organic solar cells.

### Mechanism of Generating Attractive Force Between PQT-12 and PSS

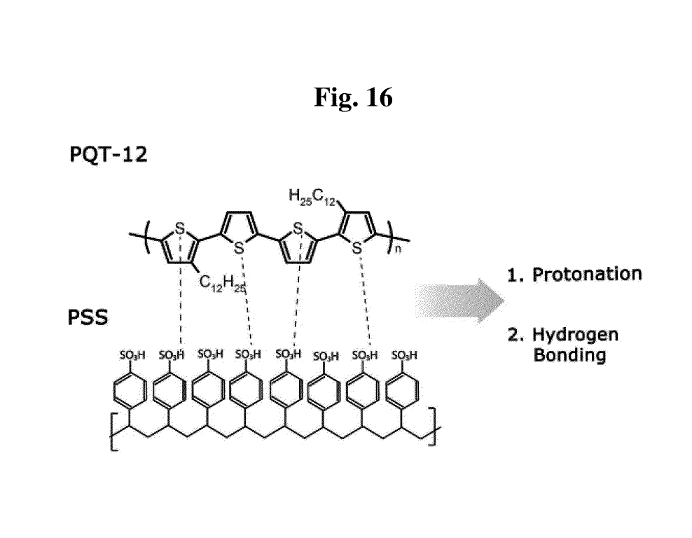

FIG. 16 shows a mechanism of generating attractive force between PQT-12 as a conjugated organic material and PSS as a polymeric organic acid.

Referring to FIG. 16, formation of crystal seeds in a solution is caused by protonation and hydrogen bonding.

Since the structure of PQT-12 is very similar to that of P3HT, and particularly has a sulfur (S) atom capable of interacting with PSS, PQT-12 can has strong attractive force with PSS.

### EXPERIMENTAL EXAMPLE 4

Performance of OFET devices using a PQT:PSS thin film as an active channel was measured.

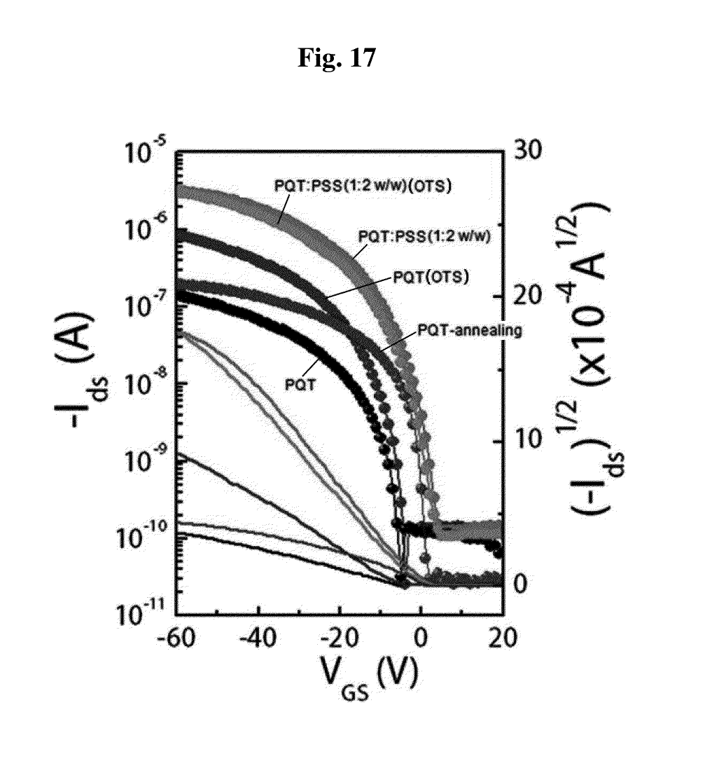

FIG. 17 shows graphs depicting characteristics of OFET devices using PQT:PSS thin films.

TABLE 4

| Condition | Mobility (cm²/Vs) |
|---|---|
| PQT-12 | 1.40 × 10⁻⁴ |
| PQT-12 (annealing) | 1.34 × 10⁻⁴ |
| PQT-12 (OTS) | 1.19 × 10⁻³ |
| PQT-12:PSS (1:2 w/w) | 4.53 × 10⁻³ |
| PQT-12:PSS (1:2 w/w) (OTS) | 4.23 × 10⁻³ |

Referring to FIG. 17 and Table 4, the OFET device using the PQT thin film, which was not subjected to any treatment, exhibited a low electric charge mobility of 1.40×10⁻⁴ cm²/V·S, whereas the OFET device using the PQT thin film subjected to annealing or OTS treatment exhibited electric charge mobility similar to this or an increased electric charge mobility of about 1.2×10⁻⁴ cm²/V·S.

On the contrary, the OFET device using the PQT:PSS (1:2 w/w) thin film exhibited the highest electric charge mobility of 4.5x10⁻³ cm²/V·S even without any treatment.

This is 20 times the electric charge mobility of an existing OFET device which was not subjected to any treatment.

Although the PQT:PSS (1:2 w/w) dispersion was coated onto a substrate subjected to OTS treatment, there were few changes in electric charge mobility. From this result, it can be seen that, since a crystal structure was formed in the PQT:PSS mixed solution due to interaction between the two polymers as in the P3HT:PSS mixed solution, induction of crystallinity through chemical treatment on a surface of dielectrics had a low effect.

Thus, the device including the PQT:PSS thin film had higher electric charge mobility than the device in which the PQT thin film was formed on the substrate subjected to OTS treatment. From this result, it can be seen that the OFET device can exhibit significantly improved electric charge mobility despite reduction of a chemical surface treatment which is not applicable to actual plastic substrates.

Changes in performance of PQT according to temperature change were analyzed.

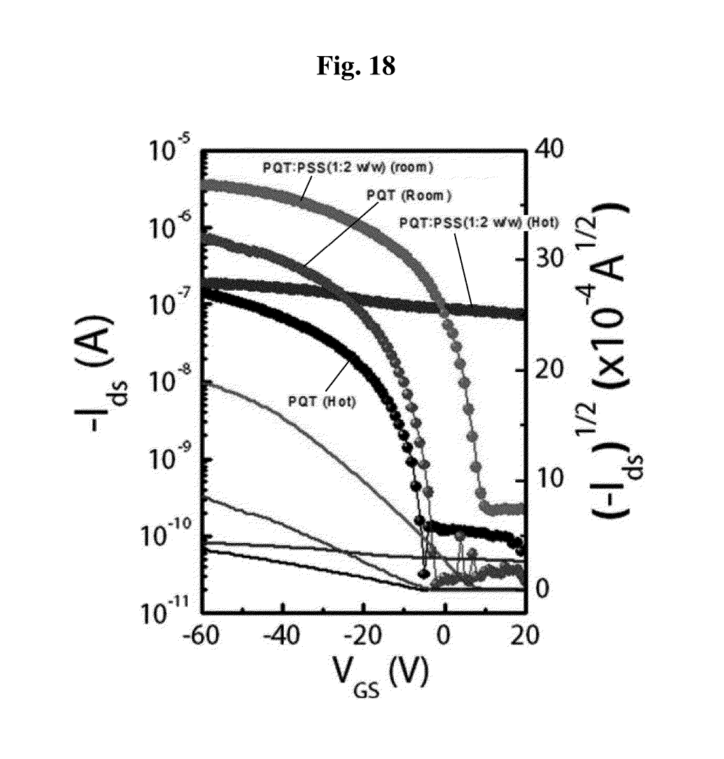

FIG. 18 shows graphs depicting characteristics of OFET devices using PQT:PSS thin films.

Referring to FIG. 18, since a long alkyl chain is not continuously bonded to the backbone in PQT, PQT has molecular structures, which are likely to be bonded to each other and agglomerate well like interdigitating structures, and thus is present in gel form at room temperature.

Thus, since it is extremely difficult to prepare a thin film through a solution process using PQT in this form, this solution is heated to be sufficiently melted for formation of the thin film.

That is, it was confirmed that, even though PQT and PSS were simply mixed, a thin film could be sufficiently formed at room temperature, and the OFET device had higher electric charge mobility than a device using a thin film prepared by heating.

Thus, it can be seen that, since strong interaction between PSS and PQT promotes removal of agglomeration and induction of high crystallinity, the OFET device had a high electric charge mobility of 5.6×10⁻cm²/V·S despite coating at room temperature.

Although the present invention has been described with reference to some embodiments in conjunction with the accompanying drawings, it should be understood that the foregoing embodiments are provided for illustration only and are not to be construed in any way as limiting the present invention, and that various modifications, changes, alterations, and equivalent embodiments can be made by those skilled in the art without departing from the spirit and scope of the invention.

What is claimed is:

1. An organic semiconductor compound thin film comprising:
a conjugated organic material comprising an unshared electron pair-containing sulfur or nitrogen atom and exhibiting semiconductivity; and
a polymeric organic acid bonded to the conjugated organic material through hydrogen bonding and protonation.

2. The organic semiconductor compound thin film according to claim 1, wherein the conjugated organic material is P3HT, PDVT-10, PQT, or DTS(PTTh₂)₂.

3. The organic semiconductor compound thin film according to claim 1, wherein the polymeric organic acid is PSS.

4. A method of fabricating an organic semiconductor compound thin film, comprising:
preparing a first dispersion in which a conjugated organic material comprising an unshared electron pair-containing sulfur or nitrogen atom and exhibiting semiconductivity is dissolved in an organic solvent;
forming a crystal seed in which the conjugated organic material and a polymeric organic acid are bonded to each other by adding the polymeric organic acid to the first dispersion; and
forming an organic semiconductor compound thin film by coating the first dispersion having the crystal seed formed therein onto a solid matrix.

5. The method according to claim 4, wherein the conjugated organic material is bonded to the polymeric organic acid through hydrogen bonding and protonation.

6. The method according to claim 4, wherein the conjugated organic material is P3HT, PDVT-10, PQT, or DTS(PTTh₂)₂.

7. The method according to claim 4, wherein the polymeric organic acid is PSS.

8. An organic electronic device comprising: the organic semiconductor compound thin film according to claim 1.

9. The organic electronic device according to claim 8, wherein the organic electronic device is an organic solar cell, the organic solar cell comprising:
a cathode;
an anode; and
a photoactive layer interposed between the cathode and the anode, the photoactive layer comprising an electron donor layer and an electron acceptor layer, the electron donor layer being the organic semiconductor compound thin film according to claim 8.

10. The organic electronic device according to claim 8, wherein the organic electronic device is an organic field effect transistor, the organic field effect transistor comprising:
a source electrode;
a drain electrode;
a gate electrode; and
an active channel interposed between the source electrode and the drain electrode, the active channel being the organic semiconductor compound thin film according to claim 8.
